(19) United States
(12) Patent Application Publication
(10) Pub. No.: US 2023/0022989 A1
(43) Pub. Date: Jan. 26, 2023

(54) SUSPENDED PIEZOELECTRIC ULTRASONIC TRANSDUCER AND MANUFACTURING THEREOF

(71) Applicant: SONICMEMS (ZHENGZHOU) TECHNOLOGY CO., LTD., Zhengzhou (CN)

(72) Inventor: Yi-Hsiang Chiu, Taipei City (TW)

(21) Appl. No.: 17/466,547

(22) Filed: Sep. 3, 2021

(30) Foreign Application Priority Data
Jul. 20, 2021 (TW) 110126698

(51) Int. Cl. H01L 41/09; H01L 41/113; H01L 41/47

(52) U.S. Cl. CPC H01L 41/096; H01L 41/1132; H01L 41/47

(57) ABSTRACT

A suspended piezoelectric ultrasonic transducer includes a semiconductor substrate and a piezoelectric ultrasonic sensing element. The semiconductor substrate includes a columnar arrangement area, a peripheral wall, and one or more bridge portions. A cavity is between the columnar arrangement area and the peripheral wall. The cavity surrounds the columnar arrangement area, and the bridge portion is connected to the columnar arrangement area and the peripheral wall. The piezoelectric ultrasonic sensing element is disposed on the columnar arrangement area. Through providing the cavity and the bridge portion on the semiconductor substrate, the resonance frequency, the acoustic pressure, and the emitting angle of the transducer can be adjusted, thereby providing a greater manufacturing tolerance for the transducer.

### CROSS-REFERENCE TO RELATED APPLICATION

This non-provisional application claims priority under 35 U.S.C. § 119(a) to Patent Application No. 110126698 in Taiwan, R.O.C. on Jul. 20, 2021, the entire contents of which are hereby incorporated by reference.

### BACKGROUND

### Technical Field

The instant disclosure relates to sensing fields, in particular, to suspended piezoelectric ultrasonic transducer and a manufacturing method thereof.

### Related Art

In recent years, ultrasonic sensors are widely utilized in fingerprint recognition, sweeping robots, and other products. Along with the refinement of the products, semiconductor wafer-scale manufacturing processed are utilized for the ultrasonic sensors. In general, an ultrasonic sensor known to the inventor clearly identifies the incident waves and the reflected waves through a vacuum cavity, such that the ultrasonic sensor provides recognition function.

### SUMMARY

However, regarding the ultrasonic sensor known to the inventor, the cavity of the ultrasonic sensor is enclosed inside the ultrasonic sensor. Therefore, when the ultrasonic sensor is manufactured, the volume of the cavity is fixed and the resonance frequency of the corresponding emitting wave is also fixed. Nevertheless, sometimes, the resonance frequency of the ultrasonic sensor cannot meet the emitting angle and the acoustic pressure in need and has to be redesigned. As a result, the cost for manufacturing an ultrasonic sensor is not low. Moreover, since the size of the ultrasonic sensor for application is reduced, the volume of the cavity is also reduced, thus the overall design of the ultrasonic sensor is further limited by the manufacturing tolerance.

In view of this, in one embodiment of the instant disclosure, a suspended piezoelectric ultrasonic transducer is provided. The suspended piezoelectric ultrasonic transducer comprises a semiconductor substrate and a piezoelectric ultrasonic sensing element. The semiconductor substrate comprises a columnar arrangement area, a peripheral wall, and at least one bridge portion. A cavity is between the columnar arrangement area and the peripheral wall. The cavity surrounds the columnar arrangement area, and the at least one bridge portion is connected to the columnar arrangement area and the peripheral wall. The piezoelectric ultrasonic sensing element is disposed on the columnar arrangement area.

In some embodiments, the semiconductor substrate further comprises at least one through hole, and the at least one through hole is defined through the semiconductor substrate and is in communication with the cavity.

Specifically, in some embodiments, the at least one through hole is adjacent to the columnar arrangement area.

Specifically, in some embodiments, the semiconductor substrate comprises a plurality of through holes. The through holes are defined through the semiconductor substrate, distributed around a periphery of the columnar arrangement area, and in communication with the cavity.

In some embodiments, the semiconductor substrate comprises a plurality of the bridge portions, and each of the bridge portions is connected to the columnar arrangement area and the peripheral wall.

Specifically, in some embodiments, the bridge portions are symmetrically arranged around the periphery of the columnar arrangement area.

In some embodiments, a width of the piezoelectric ultrasonic sensing element is less than the width of the columnar arrangement area.

In some embodiments, a thickness of the semiconductor substrate is in a range between 200 μm and 700 μm.

In some embodiments, a length of the at least one bridge portion is less than 1000 μm.

Moreover, a manufacturing method of suspended piezoelectric ultrasonic transducer is also provided. The method comprises a defining step, an element arrangement step, a through hole forming step, and a cavity forming step. In the defining step, a semiconductor substrate is provided, and a columnar arrangement area is defined on the semiconductor substrate. In the member arranging step, a piezoelectric ultrasonic sensing element is formed on the columnar arrangement area. In the through hole forming step, a through hole is formed on the semiconductor substrate, and the through hole is defined through the semiconductor substrate. In the cavity forming step, a portion of the semiconductor substrate adjacent to the columnar arraignment area is removed along the through hole, so that a cavity is formed on the semiconductor substrate and surrounds a periphery of the columnar arrangement area. An outer periphery of the cavity is a peripheral wall, the cavity is in communication with the through hole, and at least one bridge portion is connected between the columnar arrangement area and the peripheral wall.

In some embodiments, the manufacturing method further comprises a substrate thinning step before the through hole forming step. In the substrate thinning step, a thickness of the semiconductor substrate is reduced. Specifically, in some embodiments, the thickness of the semiconductor substrate is in a range between 200 μm and 700 μm.

In some embodiments, in the through hole forming step, a plurality of the through hole is formed. The through holes are defined through the semiconductor substrate, distributed around the periphery of the columnar arrangement area, and in communication with the cavity.

In some embodiments, in the cavity forming step, the semiconductor substrate comprises a plurality of the bridge portions. Each of the bridge portions is connected to the columnar arrangement area and the peripheral wall.

Specifically, in some embodiments, the bridge portions are symmetrically arranged around the periphery of the columnar arrangement area.

In some embodiments, a thickness of the semiconductor substrate is in a range between 200 μm and 700 μm.

In some embodiments, a length of the at least one bridge portion is less than 1000 μm.

According to one or some embodiments of the instant disclosure, after the piezoelectric ultrasonic sensing element is manufactured, the cavity is further provided on the semiconductor substrate. Moreover, the semiconductor substrate is connected to the piezoelectric ultrasonic sensing element disposed on the columnar arrangement area through the reserved bridge portion. Hence, not only the resonance frequency of the transducer can be adjusted, but also the acoustic pressure and the emitting angle can be adjusted, thereby providing a greater manufacturing tolerance for the transducer.

### BRIEF DESCRIPTION OF THE DRAWINGS

The disclosure will become more fully understood from the detailed description given herein below for illustration only, and thus not limitative of the disclosure, wherein:

FIG. 1 illustrates a top view of a suspended piezoelectric ultrasonic transducer according to a first embodiment of the instant disclosure;

FIG. 2 illustrates a cross-sectional view along line A-A shown in FIG. 1;

FIG. 3 illustrates a top view of a suspended piezoelectric ultrasonic transducer according to a second embodiment of the instant disclosure;

FIG. 4 illustrates a top view of a suspended piezoelectric ultrasonic transducer according to a third embodiment of the instant disclosure; and

FIG. 5 illustrates a flowchart of a manufacturing method of suspended piezoelectric ultrasonic transducer according to an exemplary embodiment of the instant disclosure.

### DETAILED DESCRIPTION

It should be understood that, when an element is referred to as being “on”, “connected to”, or “disposed on” another element, it may be directly on, connected to, or disposed on the other element, or one or more intervening elements may also be present. On the contrary, when one element is referred to as being “directly (disposed) on” or “directly connected to” another element, it can be clearly understood that there are no intervening elements between the two elements.

In addition, it will be understood that, although the terms “first”, “second”, “third”, etc. may be used herein to describe various elements, components, regions, and/or sections, these terms are only used to distinguish these elements, components, regions, and/or sections, rather than are used to represent the definite order of these elements, components, regions, and/or sections. Moreover, spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. In other words, these terms only represent a relative position relationship between the described components, not an absolute position relationship between the described components.

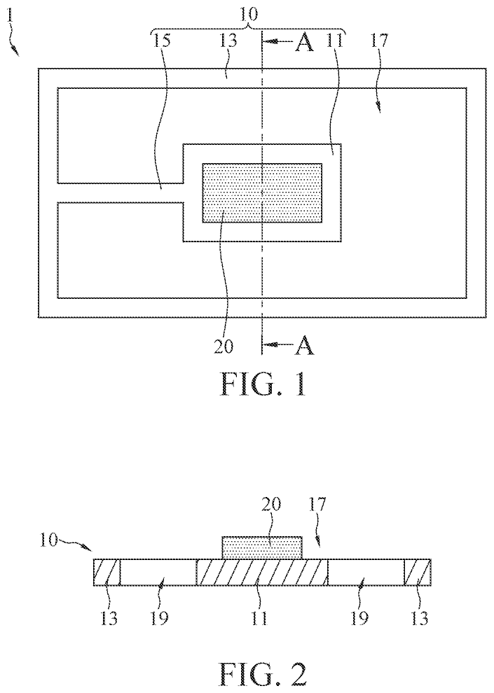

FIG. 1 illustrates a top view of a suspended piezoelectric ultrasonic transducer according to a first embodiment of the instant disclosure. FIG. 2 illustrate a cross-sectional view along line A-A shown in FIG. 1. As shown in FIG. 1 and FIG. 2, the suspended piezoelectric ultrasonic transducer 1 of the first embodiment comprises a semiconductor substrate 10 and a piezoelectric ultrasonic sensing element 20. The semiconductor substrate 10 comprises a columnar arrangement area 11, a peripheral wall 13, and a bridge portion 15. A cavity 17 is between the columnar arrangement area 11 and the peripheral wall 13. The cavity 17 surrounds the columnar arrangement area 11. The bridge portion 15 is connected to the columnar arrangement area 11 and the peripheral wall 13. The piezoelectric ultrasonic sensing element 20 is disposed on the columnar arrangement area 11.

More specifically, in one embodiment, the cavity 17 between the columnar arrangement area 11 and the peripheral wall 13 may be formed by removing a portion of the semiconductor substrate 10 through laser or etching, so that the columnar arrangement area 11 is formed as an isolated island structure in the cavity 17, thereby allowing the piezoelectric ultrasonic sensing element 20 to be suspended. Moreover, in one embodiment, the width of the piezoelectric ultrasonic sensing element 20 is less than the width of the columnar arrangement area 11. In the first embodiment, the semiconductor substrate 10 comprises only one bridge portion 15 for connecting to the columnar arrangement area 11 and the peripheral wall 13. Accordingly, when the cavity 17 of the piezoelectric ultrasonic sensing element 20 is formed, the resonance frequency of the transducer can be adjusted through changing the length of the bridge portion 15. In general, the length of the bridge portion 15 is less than 1000 μm; in one embodiment, the length of the bridge portion 15 is in the range between 300 μm and 750 μm. When the length of the bridge portion 15 is decreased, the resonance frequency of the transducer is increased, thus increasing the emitting angle. Therefore, a greater manufacturing tolerance for the transducer can be provided. Moreover, those components which are regarded as defective components owing to the improper resonance frequency can be modified and reprocessed to meet the requirements, so that a solution for fine-tuning and modifying defective component can be provided.

Please refer to FIG. 2. The semiconductor substrate 10 further comprises a at least one through hole 19. The through hole 19 is defined through the semiconductor substrate 10 and in communication with the cavity 17. More specifically, in one embodiment, the through hole 19 may be formed by laser drilling technologies and is adjacent to the columnar arrangement portion 11. Therefore, after a portion of the semiconductor substrate 10 is removed, the path for forming the cavity 17 can be provided.

More specifically, in some embodiments, the semiconductor substrate 10 may comprise a plurality of through holes 19, and the through holes 19 are distributed around a periphery of the columnar arrangement area 11.

In order to form the through hole 19 rapidly and reduce the thermal damage caused by laser processing, the semiconductor substrate 10 may be thinned before forming the through hole 19. In general, the thinning step is achieved by etching which is cheaper and faster. The thickness of the semiconductor substrate 10 directly affects the acoustic pressure of the transducer. When the thickness of the semiconductor substrate 10 is reduced, the acoustic pressure of the transducer is increased. Therefore, the step of thinning the semiconductor substrate 10 not only facilitate the formation of the though hole 19 but also allows the efficiency of the transducer to be adjustable. In this embodiment, the thickness of the semiconductor substrate 10 is in the range between 200 μm and 700 μm; in one embodiment, in the range between 300 μm and 600 μm.

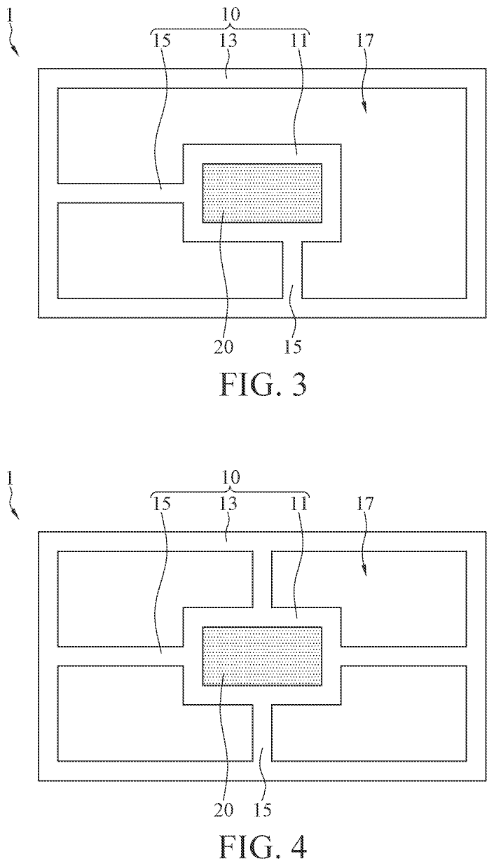

FIG. 3 illustrates a top view of a suspended piezoelectric ultrasonic transducer according to a second embodiment of the instant disclosure. FIG. 4 illustrates a top view of a suspended piezoelectric ultrasonic transducer according to a third embodiment of the instant disclosure. As shown in FIG. 3 and FIG. 4 as well as FIG. 1 and FIG. 2, in the second embodiment and the third embodiment of the suspended piezoelectric ultrasonic transducer, the number of the bridge portion are different from that in the first embodiment. in the second embodiment, the suspended piezoelectric ultrasonic transducer has two bridge portions 15, and in the third embodiment, the suspended piezoelectric ultrasonic transducer has four bridge portions 15. Each of the bridge portions 15 is connected to the columnar arrangement area 11 and the peripheral wall 13.

More specifically, in the third embodiment, the bridge portions 15 are symmetrically arranged around the periphery of the columnar arrangement area 11. It is understood that, the embodiments are provided as illustrative purposes, and the number, the position, and the arrangement of the bridge portions 15 may be adjusted according to actual requirements. More specifically, in one embodiment, the total length of the bridge portions 15 is inversely proportional to the resonance frequency and the emitting angle of the transducer. Therefore, the resonance frequency and the emitting angle of the transducer can be adjusted through adjusting the number and the total length of the bridge portions 15.

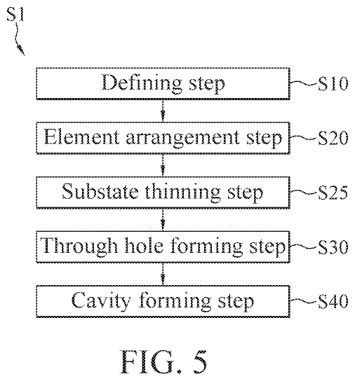

FIG. 5 illustrates a flowchart of a manufacturing method of suspended piezoelectric ultrasonic transducer according to an exemplary embodiment of the instant disclosure. As shown in FIG. 5 as well as FIG. 1 to FIG. 4, the manufacturing method S1 of suspended piezoelectric ultrasonic transducer comprises a defining step S10, an element arrangement step S20, a through hole forming step S30, and a cavity forming step S40. In the defining step S10, a semiconductor substrate 10 is provided, and a columnar arrangement area 11 is defined on the semiconductor substrate 10. In the element arrangement step S20, a piezoelectric ultrasonic sensing element 20 is formed on the columnar arrangement area 11.

In the through hole forming step S30, a through hole 19 is formed on the semiconductor substrate 10, and the through hole 19 is defined through the semiconductor substrate 10. In the cavity forming step S40, along the through hole 10, a portion of the semiconductor substrate 10 adjacent to the columnar arrangement area 11 is removed, so that a cavity 17 is formed on the semiconductor substrate 10 and surrounds a periphery of the columnar arrangement area 11. An outer periphery of the cavity 17 is a peripheral wall. The cavity 17 is in communication with the through hole 19. The columnar arrangement area 11 and the peripheral wall 13 are connected to each other through at least one bridge portion 15 reserved on the semiconductor substrate 10. In this embodiment, the cavity forming step S40 may be achieved by removing the semiconductor material with laser or etching.

Please refer to FIG. 5. Moreover, in some embodiments, the manufacturing method S1 may further comprise a substrate thinning step S30 before the through hole forming step S25. In the substrate thinning step S25, the thickness of the semiconductor substrate 10 is reduced. The step of thinning the semiconductor substrate 10 not only facilitate the formation of the though hole 19 but also allows the efficiency of the transducer to be adjustable.

As above, according to one or some embodiments of the instant disclosure, after the piezoelectric ultrasonic sensing element 20 is manufactured, the cavity 17 is further provided on the semiconductor substrate 10. Moreover, the semiconductor substrate 10 is connected to the piezoelectric ultrasonic sensing element 20 disposed on the columnar arrangement area 11 through the reserved bridge portion 15. Hence, not only the resonance frequency of the transducer can be adjusted, but also the acoustic pressure and the emitting angle can be adjusted, thereby providing a greater manufacturing tolerance for the transducer.

While the instant disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A suspended piezoelectric ultrasonic transducer comprising:
a semiconductor substrate comprising a columnar arrangement area, a peripheral wall, and at least one bridge portion, wherein a cavity is between the columnar arrangement area and the peripheral wall, the cavity surrounds the columnar arrangement area, and the at least one bridge portion is connected to the columnar arrangement area and the peripheral wall; and
a piezoelectric ultrasonic sensing element disposed on the columnar arrangement area.

2. The suspended piezoelectric ultrasonic transducer according to claim 1, wherein the semiconductor substrate further comprises at least one through hole, and the at least one through hole is defined through the semiconductor substrate and is in communication with the cavity.

3. The suspended piezoelectric ultrasonic transducer according to claim 2, wherein the at least one through hole is adjacent to the columnar arrangement area.

4. The suspended piezoelectric ultrasonic transducer according to claim 2, wherein the semiconductor substrate comprises a plurality of through holes; the through holes are defined through the semiconductor substrate, distributed around a periphery of the columnar arrangement area, and in communication with the cavity.

5. The suspended piezoelectric ultrasonic transducer according to claim 1, wherein the semiconductor substrate comprises a plurality of the bridge portions, and each of the bridge portions is connected to the columnar arrangement area and the peripheral wall.

6. The suspended piezoelectric ultrasonic transducer according to claim 5, wherein the bridge portions are symmetrically arranged around the periphery of the columnar arrangement area.

7. The suspended piezoelectric ultrasonic transducer according to claim 1, wherein a width of the piezoelectric ultrasonic sensing element is less than a width of the columnar arrangement area.

8. The suspended piezoelectric ultrasonic transducer according to claim 1, wherein a thickness of the semiconductor substrate is in a range between 200 μm and 700 μm.

9. The suspended piezoelectric ultrasonic transducer according to claim 1, wherein a length of the at least one bridge portion is less than 1000 μm.

10. A manufacturing method of suspended piezoelectric ultrasonic transducer, comprising:
a defining step: providing a semiconductor substrate, wherein a columnar arrangement area is defined on the semiconductor substrate;
an element arrangement step: forming a piezoelectric ultrasonic sensing element on the columnar arrangement area;
a through hole forming step: forming a through hole on the semiconductor substrate, wherein the through hole is defined through the semiconductor substrate; and
a cavity forming step: removing a portion of the semiconductor substrate adjacent to the columnar arrangement area along the through hole, so that a cavity is formed on the semiconductor substrate and surrounds a periphery of the columnar arrangement area; an outer periphery of the cavity is a peripheral wall, the cavity is in communication with the through hole, and at least one bridge portion is connected between the columnar arrangement area and the peripheral wall.

11. The manufacturing method according to claim 10, further comprising a substrate thinning step before the through hole forming step, wherein in the substrate thinning step, a thickness of the semiconductor substrate is reduced.

12. The manufacturing method according to claim 11, wherein the thickness of the semiconductor substrate is in a range between 200 μm and 700 μm.

13. The manufacturing method according to claim 10, wherein the thickness of the semiconductor substrate is in a range between 200 μm and 700 μm.

14. The manufacturing method according to claim 10, wherein in the through hole forming step, a plurality of the through hole is formed, and the through holes are defined through the semiconductor substrate, distributed around the periphery of the columnar arrangement area, and in communication with the cavity.

15. The manufacturing method according to claim 10, wherein in the cavity forming step, the semiconductor substrate comprises a plurality of the bridge portions, and each of the bridge portions is connected to the columnar arrangement area and the peripheral wall of the cavity.

16. The manufacturing method according to claim 15, wherein the bridge portions are symmetrically arranged around the periphery of the columnar arrangement area.

17. The manufacturing method according to claim 10, wherein a width of the piezoelectric ultrasonic sensing element is less than a width of the columnar arrangement area.

18. The manufacturing method according to claim 10 wherein, a length of the at least one bridge portion is less than 1000 μm.
